(19) United States
(12) Patent Application Publication
(10) Pub. No.: US 2015/0014026 A1
(43) Pub. Date: Jan. 15, 2015

(54) PRINTED CIRCUIT BOARD AND MANUFACTURING METHOD THEREOF

(71) Applicant: Samsung Electro-Mechanics Co., Ltd., Suwon (KR)

(72) Inventors: Jun Yong PARK, Busan (KR); Jae Woo Joung, Busan (KR)

(73) Assignee: Samsung Electro-Mechanics Co., Ltd., Suwon (KR)

(21) Appl. No.: 14/073,416

(22) Filed: Nov. 6, 2013

(30) Foreign Application Priority Data
Jul. 9, 2013 (KR) 10-2013-0080409

(51) Int. Cl. B32B 37/00; H05K 3/36; H05K 3/46; H05K 1/02; H05K 1/14

(52) U.S. Cl. CPC B32B 37/00; H05K 1/0216; H05K 1/148; H05K 1/028; H05K 3/4611; H05K 3/361; H05K 2201/0723
USPC 174/254; 156/243

(57) ABSTRACT

Disclosed herein are a printed circuit board and a manufacturing method thereof. The printed circuit board includes a rigid substrate having a solder resist applied thereon and a flexible substrate connected to the rigid substrate in order to increase productivity by simplifying a process of manufacturing the printed circuit board. The manufacturing method includes: attaching a coverlay onto an upper surface of the flexible substrate; attaching an electromagnetic interference (EMI) film onto an upper surface of the coverlay; attaching and pressurizing a substrate molding subsidiary material onto an upper surface of the EMI film; and separating the substrate molding subsidiary material.

### CROSS REFERENCE(S) TO RELATED APPLICATIONS

This application claims the benefit under 35 U.S.C. Section 119 of Korean Patent Application Serial No. 10-2013-0080409, entitled “Printed Circuit Board and Manufacturing Method Thereof” filed on Jul. 9, 2013, which is hereby incorporated by reference in its entirety into this application.

### BACKGROUND OF THE INVENTION

1. Technical Field

The present invention relates to a printed circuit board and a manufacturing method thereof, and more particularly, to a printed circuit board capable of increasing productivity by simplifying a process of manufacturing the printed circuit board and a manufacturing method thereof.

2. Description of the Related Art

Recently, in accordance with portability and high-functionality of an electronic device, and Internet, moving images, and transmission, reception of high capacity data, and the like, a design of a printed circuit board is more complicated and a demand for a high-density and miniaturized circuit has gradually increased.

Therefore, the printed circuit board accommodated in the electronic device is thinned and miniaturized, such that a line width of a wire of the printed circuit board becomes small and a configuration of the printed circuit board has been manufactured in a multi-layer structure rather than a single layer structure in order to implement functions of the printed circuit board.

Currently, in a process of manufacturing a rigid flexible printed circuit board, a coverlay, an electro-magnetic interference (EMI), and the like are manufactured on a flexible substrate according to the respective processes, are laminated on an insulating material, and are then cured.

In this case, when manufacturing the printed circuit board, impedance has magnified as a very important management factor according to slimness of a product and an increase in a response speed. In order to improve impedance characteristic, the EMI is often removed to expand a ground region.

However, there is a limitation in improving performance of the impedance by only the removal of the EMI and the expansion of the ground region. Therefore, in order to improve this, the coverlay is molded, exposing and developing processes are performed, and an EMI film insulating layer is molded at a position to which a copper (Cu) post is exposed, such that radiation characteristic of the product has improved.

However, in spite of the above-mentioned process improvement, a molding temperature is increased due to increased processes, which may cause deformation in the product.

### RELATED ART DOCUMENT

### Patent Document

(Patent Document 1) Cited Reference: Korean Patent Laid-Open Publication No. 2012-44271

### SUMMARY OF THE INVENTION

An object of the present invention is to provide a printed circuit board capable of increasing productivity and product property by simplifying a process of manufacturing the printed circuit board and a manufacturing method thereof.

Another object of the present invention is to minimize deformation in the printed circuit board caused by heat using the simplification of the manufacturing process.

According to an exemplary embodiment of the present invention, there is provided a manufacturing method of a printed circuit board including a rigid substrate having a solder resist applied thereon and a flexible substrate connected to the rigid substrate, the method including: attaching a coverlay onto an upper surface of the flexible substrate; attaching an electromagnetic interference (EMI) film onto an upper surface of the coverlay; attaching and pressurizing a substrate molding subsidiary material onto an upper surface of the EMI film; and separating the substrate molding subsidiary material.

The coverlay and the EMI film may be attached and cured by the substrate molding subsidiary material.

The substrate molding subsidiary material may be thermoformed at a temperature of 170° C. or more and may be applied and cured with a pressure of 25 kg/cm² or more.

### BRIEF DESCRIPTION OF THE DRAWINGS

FIG. 1 is an illustration view showing a printed circuit board according to an exemplary embodiment of the present invention; and

FIGS. 2A to 2F are illustration views showing processes of manufacturing the printed circuit board according to an exemplary embodiment of the present invention.

### DESCRIPTION OF THE PREFERRED EMBODIMENTS

Terms and words used in the present specification and claims are not to be construed as a general or dictionary meaning, but are to be construed to meaning and concepts meeting the technical ideas of the present invention based on a principle that the inventors can appropriately define the concepts of terms in order to describe their own inventions in the best mode.

Throughout the present specification, unless explicitly described to the contrary, “comprising” any components will be understood to imply the inclusion of other elements rather than the exclusion of any other elements.

Hereinafter, an exemplary embodiment of the present invention will be described in detail with reference to the accompanying drawings.

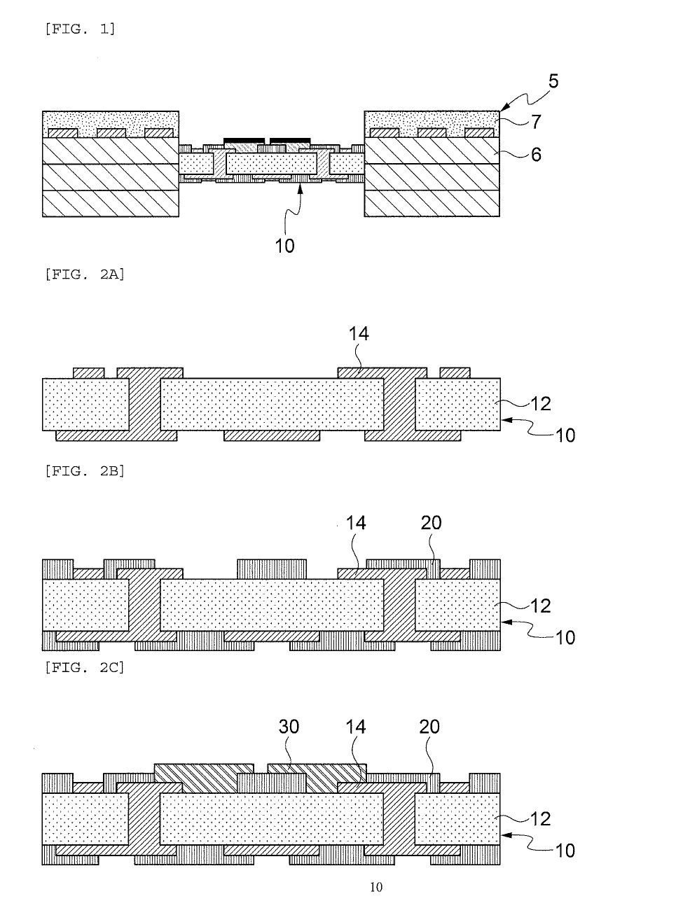

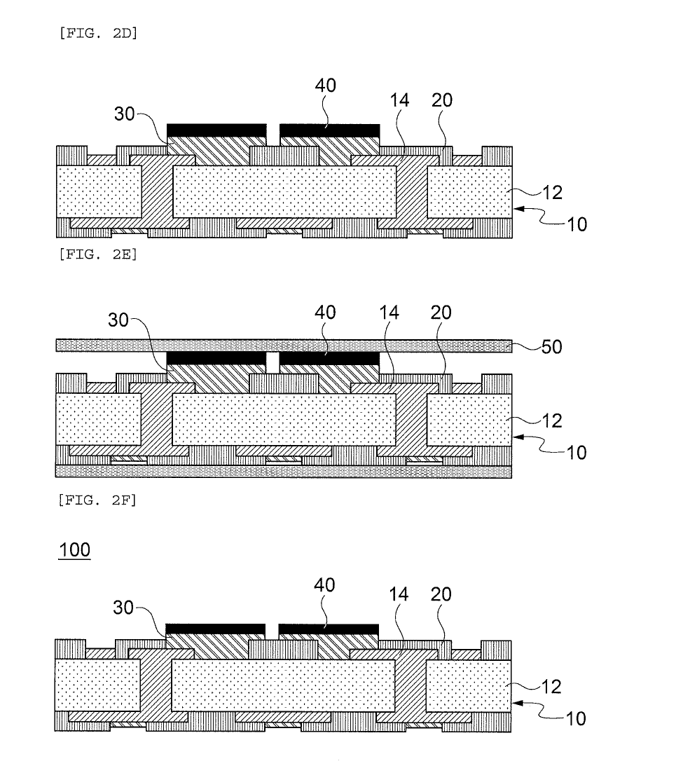

FIG. 1 is an illustration view showing a printed circuit board according to an exemplary embodiment of the present invention and FIGS. 2A to 2F are illustration views showing processes of manufacturing the printed circuit board according to an exemplary embodiment of the present invention.

As shown, the printed circuit board 100 according to the exemplary embodiment of the present invention includes a rigid substrate 5 to which a solder resist 7 is applied and a flexible substrate 10, and minimizes deformation in the flexible substrate 10 by laminating a coverlay 30, and an EMI film 40, and the like on the flexible substrate 10 by the simplified laminating process.

The rigid substrate 5 having a plurality of insulating layers 6 laminated may be a build-up substrate in which a copper clad laminate (CCL) is configured or may be a substrate laminate body in which the CCL is not included.

In addition, the rigid substrate 5 may be provided with a circuit pattern (not shown) and vias according to a pre-designed pattern so as to electrically connect the laminated substrate thereto.

The solder resist 7 is applied to the rigid substrate 5 having the circuit pattern formed as described above. The solder resist 7, which is to protect an exposure of the circuit pattern and minimize the deformation in the rigid substrate 5, may be applied onto an upper surface of the insulating layer 6.

Meanwhile, the coverlay 30 is attached or applied onto the flexible substrate 10 in a B-stage state.

The coverlay 30, which is configured to protect the circuit pattern exposed on the upper surface of the flexible substrate 10, is attached onto the surface of the flexible substrate 10.

After the coverlay 30 is attached as described above, the EMI film 40 is attached or applied onto an upper portion of the coverlay 30 in the B-stage state. The EMI film 40 blocks an electromagnetic wave from being applied to the substrate from the outside or blocks an electromagnetic wave generated from the circuit pattern from being transmitted to the outside.

Once the EMI film 40 is laminated in a state in which it is attached, a thermoforming is performed while a substrate molding subsidiary material 50 such as a hot press machine presses an upper surface of the EMI film 40.

At the time of pressurizing, a temperature of the substrate molding subsidiary material 50 is set to 170° C. or more, such that the EMI film 40 and the coverlay 30 are thermoformed, and a pressure thereof is set to 25 kg/cm² or more, such that the EMI film 40 and the coverlay 30 are cured.

When the thermoforming and the curing are completed by the substrate molding subsidiary material 50, the substrate molding subsidiary material 50 is separated from the EMI film 40.

As described above, if the substrate molding subsidiary material 50 is pressurized at a high temperature in a state in which the coverlay 30 and the EMI film 40 are attached onto the surface of the flexible substrate 10, processes of pressurizing the coverlay 30 in a state in which the coverlay 30 is attached using the substrate molding subsidiary material 50 and again attaching and then pressurizing the EMI film 40 onto the upper portion of the coverlay 30 may be simplified to one pressurization process, thereby making it possible to simplify the process.

In addition, the simplification of the process has actually a great effect on decreasing moisture absorption rate of the flexible substrate 10. That is, the moisture absorption rate of the flexible substrate 10 is increased in proportion to a process time of manufacturing the printed circuit board 100 and when the moisture absorption rate is high, an defective rate of the product may be increased.

Particularly, a moisture absorption amount has a large difference depending on temperatures of a summer season and a winter season and product defect caused by moisture absorption defect is an important consideration in designing the printed circuit board 100.

Therefore, when the manufacturing process of the printed circuit board 100 according to the exemplary embodiment of the present invention is simplified, the moisture absorption rate is decreased, such that product property may be increased and production costs may also be decreased.

According to the exemplary embodiment of the present invention, the printed circuit board and the manufacturing method thereof minimize the deformation in the printed circuit board generated during the manufacturing process by the simplification of the manufacturing process, thereby making it possible to increase productivity and product property.

Although the printed circuit board and the manufacturing method thereof according to the exemplary embodiment of the present invention have been described, the present invention is not limited thereto, but those skilled in the art will appreciate that various applications and modifications are possible.

What is claimed is:

1. A manufacturing method of a printed circuit board including a rigid substrate having a solder resist applied thereon and a flexible substrate connected to the rigid substrate, the method comprising:
attaching a coverlay onto an upper surface of the flexible substrate;
attaching an electromagnetic interference (EMI) film onto an upper surface of the coverlay;
attaching and pressurizing a substrate molding subsidiary material onto an upper surface of the EMI film; and
separating the substrate molding subsidiary material.

2. The method according to claim 1, wherein the coverlay and the EMI film are attached and cured by the substrate molding subsidiary material.

3. The method according to claim 1, wherein the substrate molding subsidiary material is thermoformed at a temperature of 170° C. or more.

4. The method according to claim 1, wherein the substrate molding subsidiary material is applied and cured with a pressure of 25 kg/cm² or more.

5. A printed circuit board manufactured by the manufacturing method according to claim 1.

6. The method according to claim 3, wherein the substrate molding subsidiary material is applied and cured with a pressure of 25 kg/cm² or more.
